(19) United States
(12) Patent Application Publication
(10) Pub. No.: US 2007/0259184 A1
(43) Pub. Date: Nov. 8, 2007

(54) Method of mounting objects for chemical vapour deposition

(75) Inventors: Phil J. Martin, Quakers Hill (AU); Avi Bendavid, North Bondi (AU); Edward Preston, West Lindfield (AU); Mark Gross, Lindfield (AU)

Correspondence Address: MERCHANT & GOULD PC, P.O. BOX 2903, MINNEAPOLIS, MN, 55402-0903, US

(73) Assignee: Commonwealth Scientific and Industrial Research Organisation, Campbell (AU)

(21) Appl. No.: 11/442,804

(22) Filed: May 30, 2006

(30) Foreign Application Priority Data
May 4, 2006 (AU) 2006902334

(51) Int. Cl. C23C 16/26; C23C 16/00; H05H 1/24; B32B 9/00

(52) U.S. Cl. 428/408; 427/255.28; 427/569; 427/249.7

(57) ABSTRACT

A method of coating a surface of an article with a chemical vapour deposition coating such as a diamond like carbon by, for example, pulse DC PACVD or RF PACVD, comprising providing an active electrode, shielding the active electrode with a dielectric shield having at least one aperture to permit access to the active electrode, closing the aperture with a dielectricly shielded support post comprising an electively conductive core in electrical communication via the aperture with the active electrode, placing an article to be coated on the dielectricly shielded support post in electrical communication with the electively conductive core and applying a plasma to the article in presence of an electrical current to the article to provide a coating. The article may be, for example, a piston. A contiguous array of a plurality of similar articles may be simultaneously coated by the method.

### FIELD OF THE INVENTION

The invention relates to a method of mounting or fixturing items for chemical vapour deposition, and to coated objects produced by said method.

### BACKGROUND OF THE INVENTION

Chemical vapour deposition, (“CVD”) is a known technique for applying thin coatings to the surface of articles. Diamond-Like Carbon (“DLC”) coatings are of particular interest because of their nano-scale thickness, biocompatibility and because they impart high levels of hardness, low levels of friction and low wear rates to the surface of the coated object.

The general CVD process for the deposition of DLC films involves placing the article to be coated in a vacuum chamber, and contacting the article with a suitable plasma. The properties of the ultimate DLC film can be controlled by controlling the composition of the plasma and by varying processing parameters such as pressure and specific sequences of cleaning and etching. Plasmas can be generated either by applying RF energy, (“RF PACVD”), or by applying pulsed DC biased power to the article to be coated (substrate) (“DC-Pulsed PACVD”) in the presence of a precursor gas. In the case of pulsed DC PACVD, the properties of the ultimate DLC film can also be controlled by controlling the sequence in which pulsed DC bias power is applied.

The specific manner of fixturing items inside the vacuum deposition chamber for the purposes of applying a DLC coating can also influence the properties of the subsequent coated article.

In U.S. Pat. No. 5,653,812, Petrmichl et al describe a system for holding drills so that they can be coated with a wear resistant diamond-like carbon using RF Activated Plasma Vapour Deposition (“RF-PACVD”). A capacitively coupled RF generator operating at 13.56 MHz is connected to a powered electrode inside the deposition chamber. The active electrode has an electrically insulating dielectric block on the surface and a grounded electrically conducting plate mounted above it, through which the drills penetrate from the active electrode to the plasma above. The system provides for a method of electrically masking the plasma from the areas of the active electrode where the deposition is undesirable and restricts coating to the top exposed areas of the tools only. However, such an arrangement is typically only amenable to the coating of elongated articles where it is desirable to coat only a portion of the articles. For instance, drills and other cutting tools, when used, typically have a portion retained in a chuck or similar which does not require a high performance coating. Accordingly, other arrangements are required to coat differently shaped articles.

One of the particular uses of DLC's is in the coating of pistons, where their low coefficient of friction and good wearing properties make for ideal surfaces. However, fixturing methods such as disclosed in Petrmichl which leave the base of the articles uncoated are inherently unsuitable for the application of DLC's to articles such as piston cylinders, as a portion of the article would remain uncoated and so would retain the less desirable wear characteristics of the substrate. Accordingly, alternative fixturing methods are required to enable better coating of shaped articles with DLC's. There is also a need to increase the throughput and reproducibility of articles by improving fixturing, which is currently limited by the size of the powered electrode. Further it would be desirable if the fixturing methods could reduce the presence of unwanted edge affects.

Any discussion of the prior art throughout the specification should in no way be considered as an admission that such prior art is widely known or forms part of common general knowledge in the field.

### SUMMARY OF THE INVENTION

According to a first aspect the invention provides a method of coating a surface of an article with a chemical vapour deposition coating comprising:

providing an active electrode;

shielding said active electrode with a dielectric shield having at least one aperture to permit access to the active electrode;

closing said aperture with a dielectricly shielded support post comprising an electively conductive core in electrical communication via said aperture with said active electrode;

placing an article to be coated on said dielectricly shielded support post in electrical communication with said electrically conductive core; and

applying a plasma to said article in presence of an electrical current to the article to provide a coating.

Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The CVD coating is preferably a diamond like carbon coating. The coating is preferably applied by pulse DC PACVD. That is, the electrical current is a pulsed DC current.

The article is preferably a cup shaped article, more preferably a substantially hollow elongated cylinder of uniform cross section along its length, preferably open at one end with the other end closed or partially closed. Preferably the cylinder is of circular cross section. Most preferably, the article is a piston.

The electrically conductive core of the shielded support post is in electrical communication with the active electrode, and may be held firmly in contact by a threaded connector on either the core or the active electrode, or between the two. Other means of ensuring a firm connection may be employed, such as a tapered insert, or a sprung or otherwise resiliently biased detent means. The post can be simply placed on the active electrode if desired.

The article is preferably placed on the shielded support post so that the shielded support post is covered or substantially covered by the article. Preferably, the article covers the top of the shielded support post and substantially covers the sides of the shielded support post.

Any other suitable arrangement of a dielectrically shielded male support post with a contacted conductive core and corresponding female recess in the article may be employed. The only requirement is that the article to be coated is electrically conducting and at least a portion of said article is in electrical communication with the conducting core of the shielded support post, and ultimately the active electrode.

In order to ensure good electrical communication between the article to be coated and the electrically conducting support post, a cap may be applied to the top of the article to be coated. The cap is generally of corresponding cross section to the article to be coated. In a particularly preferred embodiment, the cap is conducting and in electronic communication with the central core of the support post. For preference, the cap is configured for engagement with the conducting core of the support post, such as by means of a thread which engages the post and cap and passes through the article, or by a post which engages and detains the cap to the post, with the article sandwiched there between. However, the cap can be non-conducting if desired.

Besides a close fitting cap, other means can be used to fix an upturned article to a support post, for example, a bolt, taper, pin, screw or a sprung or otherwise resiliently biased detent means.

In another aspect the invention provides a method of coating wherein a plurality of cylindrical objects are coaxially stacked to provide a substantially contiguous coating surface prior to being plasma coated. The articles to be coated may be in electrical communication with one another or may be in direct electrical communication with the central core of the support post, or may be in electrical communication with the conducting core via one another or via a single or plural array of connectors. The connectors may be comprised of an electrically conductive core surrounded by a dielectric shield, or more preferably, are connectors of conducting material which are shielded by the articles to be coated. A plurality of conductors may be used, or a fewer number of conductors passing through multiple articles may be employed.

A cap or other securing means as described above for singly fixed articles may sit atop the stack of coated articles.

### BRIEF DESCRIPTION OF THE DRAWINGS

FIG. 1 shows a prior art method of fixturing articles for CVD coating.

FIG. 2a shows apparatus for CVD coating of the present invention.

FIG. 2b is an expansion of FIG. 2a showing the fixturing of articles in more detail

FIG. 3 shows a powered electrode with a dielectric shield.

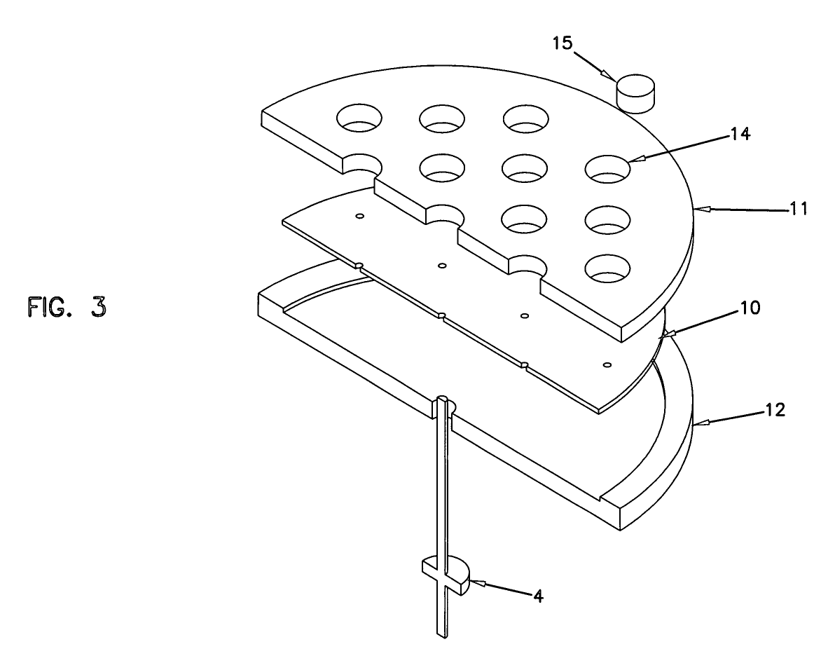

FIG. 4 shows fixturing of an article in accordance with the present invention.

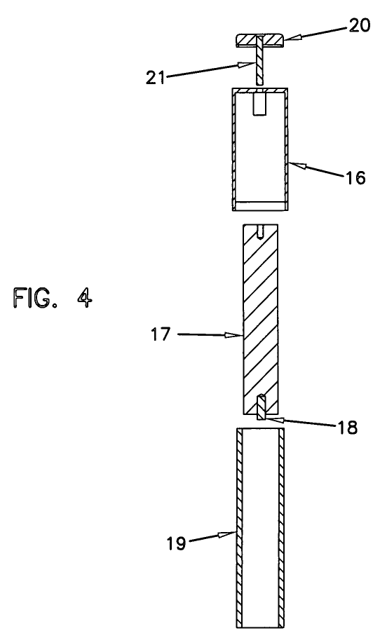

FIG. 5 shows fixturing of a plurality of articles in accordance with the present invention.

### DESCRIPTION OF THE INVENTION

The apparatus of the present invention is herein described with reference to the present invention.

The apparatus of the present invention include, in general terms, a pulsed DC power supply which powers an electrode. The electrode is within a deposition chamber. The pressure and gas composition inside the chamber are controlled by a pumping station and a gas introduction system. Connected to the electrode is a substrate fixturing system. The pulsed DC power supply acts in combination with the gas inside the chamber (a suitable hydrocarbon generating gas such as methane) to provide a plasma which coats the substrate.

The power supply, deposition chamber, pumping station and gas introduction system may be any conventional systems in the art.

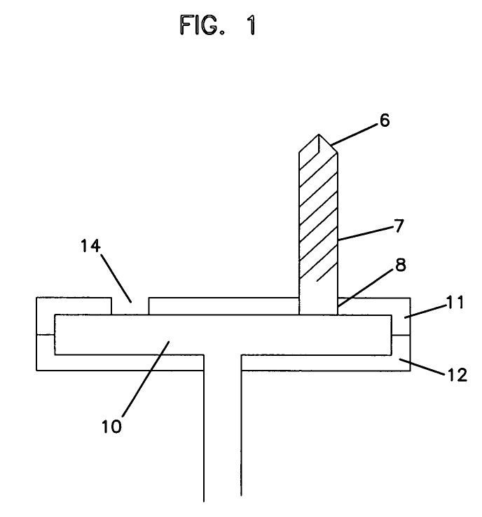

The substrate fixturing system of the prior art is shown with reference to FIG. 1. A powered electrode 10 is enclosed by top 11 and bottom 12 shield plates. The top plate is apertured 14, and holds elongate articles 6 upright in electrical communication with the plate 10. A plasma is applied, for instance, RF PACVD, and in this way, the active electrode 10 is shielded, and the portion 7 of the elongate article 6 projecting from the shield plate 11 is able coated with a layer of DLC. The elongate article is removed, with region 7 coated and the base portion 8 uncoated.

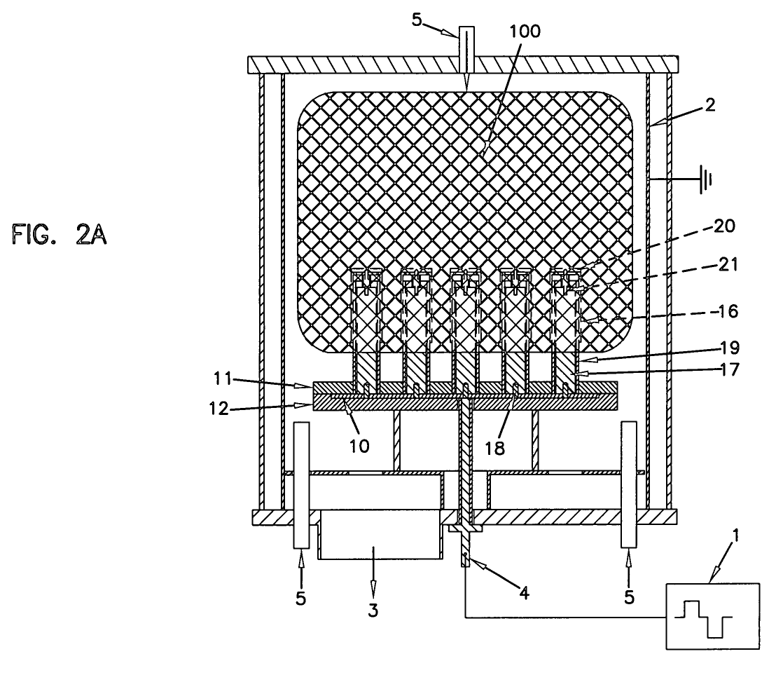

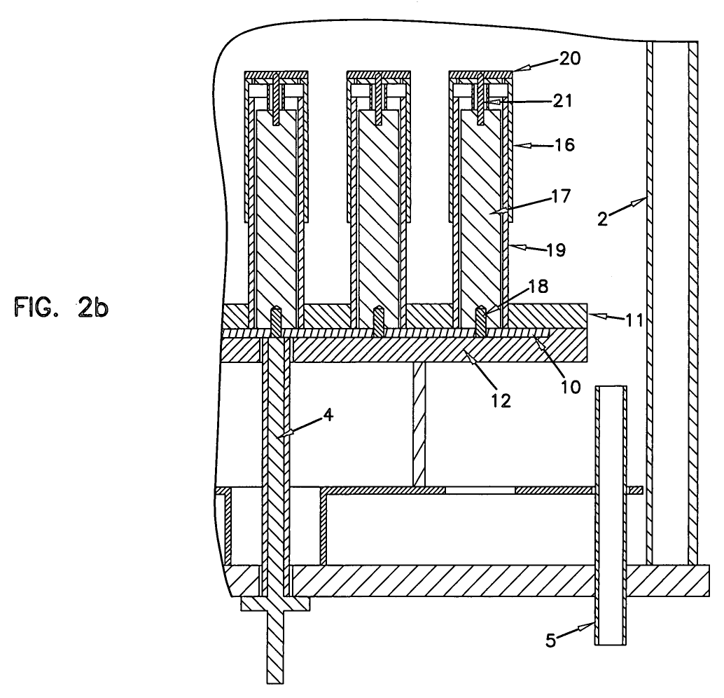

In the present invention, shown in FIGS. 2a and 2b, an active electrode 10 is connected to a pulsed DC power supply 1 by means of an electrical feedthrough 4 in the vacuum chamber 2. The bottom of active electrode 10 is covered with a dielectric material 12 such as glass and the top is covered also with dielectric material 11 which advantageously is the same material as 12. A number of apertures 14 are cut into the upper dielectric material 10 to allow for fixtures of substrates. The upper dielectric material 11 may be configured with a large number of apertures 14, however, if it is not desired to use these, they can be closed off by way of removable plugs or caps 15. Only the required areas of the active electrode are used in the coating.

In the case of cylindrically symmetrical substrates such as the cylinder 16 shown in FIG. 2, the substrates 16 are raised above the surface of the active area of the electrode 10 through the apertures by means of electrically conducting posts 17. The posts may be fixed to the active electrodes by suitable means such as threaded screws 18. A dielectric sleeve 19 surrounds the conducting post 17. The height of the post is configured so that the bottom edge of the cylindrical substrate 16 is raised off the dielectric shield 11 by approximately 3 times the plasma sheath thickness of 20-25 mm. Raising the lower edge above the active electrode results in uniform coating of the substrate along its entire length without an excessive build up of coating due to edge effects near the active electrode 10 surface.

Any surfaces that are not required to be coated, such as the mounting posts 17 and active electrode 10 are shielded from the plasma in this way.

The top of the cylinder 16 can be coated if needed. However, this is not usually subject to friction and it is preferable to avoid wasting coating material on this surface. Minimising the coating of unwanted portions of the articles can minimise the coating cost per article which can be significant in the scale up. If it is not required to coat the top surface of the cylinder 16, it can be fitted with a close fitting cap 20 either of a conducting material, such as metal or of a dielectric material. The cap is secured to the conductive core of the post by means of a screw 21, which passes through an aperture in the top of the cylinder. The presence of a cap 20 can also serve to minimise edge effects at the top of the cylinder.

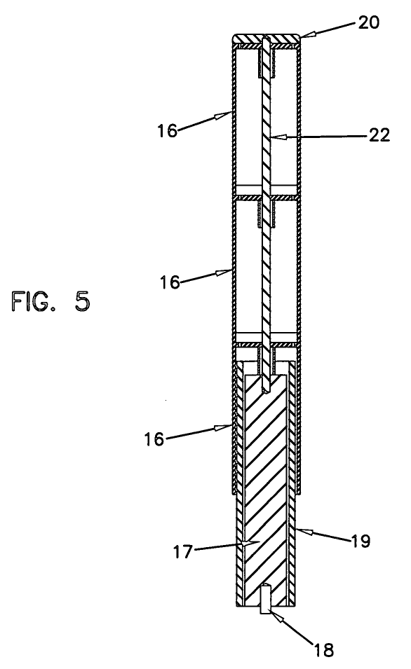

FIG. 5 shows an array of stacked cylindrical articles without the active electrode and its associated shielding.

If a large number of substrates are required to be coated they may be attached to each other vertically forming a vertical array of substrates as shown in FIG. 5. Instead of a cap 20 going on top of the article 16 sitting on the support post 17, a number of substrates 16 can be stacked. The stacks are kept in electrical communication either by contact between the articles to be coated or by means of a connector 22, or both. A cap 20 is advantageously placed on top of the stack, to ensure the stack remains in position with good electrical communication between the active electrode and all the articles to be coated.

The number of substrates that may be assembled in such a fashion depends upon the size of the active electrode and the size of the deposition chamber used.

The horizontal separation between the individual substrates or vertical assemblies of substrates on the plate is determined by the thickness of the plasma sheath that is created during pulsed DC PACVD. For pulsed DC frequencies in the range of 10 to 100 kHz, and pressures of 100-200 Pa the plasma sheath is about 6-8 mm. The separation between individual substrates or vertical assemblies of substrates should be approximately twice the plasma sheath thickness ie 12-16 mm. At such distances, there is little or no overlap of the plasma sheath between individual substrates or assemblies of substrates in uniform coating will be achieved around the exposed surface area of the substrate.

Once the fixturing is complete, the chamber 2 can be closed and evacuated, and the coating process can be commenced. Any cleaning and etching steps can be carried out depending upon the condition of the substrate and the desired coating. The chamber can be evacuated as desired by pumping station 3. The plasma precursor gas can be introduced by manifolds 5 and can be any suitable carbon source gas mix (such as a hydrocarbon) to provide a DLC coating. Suitable gas mixtures can include methane, argon, hydrogen and tetramethylsilane (Si(CH₃)₄ also known as TMS).

Pulsed DC power is then applied to the active electrode 10 in any suitable pulse sequence, to generate a plasma 100 and form the DLC coating on the substrate. Other species can be incorporated into the DLC, for example silicon, nitrogen, hydrogen if desired. Any conventional plasma or coating sequence can be applied to substrates fixed to the electrode by the methods of the present invention.

The present invention allows for complete shielding of the electrodes surface from the plasma. In the methods of the present invention only the substrates surface to be coated is exposed to the plasma and connected to the active electrodes through the mounting posts attached to the active electrode. By shielding any areas where coating is not necessary, all the available plasma power is concentrated on to the substrates only. This also improves the reproducibility of the process by stabilising the plasma.

Further, because the active electrode is covered with dielectric and is not exposed or coated (or is only minimally coated) by the plasma, the requirement for cleaning of the active electrode is minimised and the possibility of build-up of contaminates in the deposition system is reduced.

The fixturing system of the present invention can be used with RF PACVD although pulse DC PACVD is preferred for a variety of reasons. Pulse DC PACVD is not as sensitive to the ratio of the area of the active electrode to the surface of the area of the counter electrode i.e. the earth chamber wall as in the case of the art if activated plasma. As a result, the coating can be more readily duplicated independent of the chamber size and the size and number of the articles being coated. The power supply in the case of pulse DC PACVD may be coupled directly to the active electrode without the necessity of capacitive coupling as used in RF. The pulsed DC power may be increased without any modifications to the coupling as opposed to RF activated plasma where it becomes necessary to match the impedance more carefully as RF power is increased.

Pulse DC PACVD is also preferred over RF PACVD because inherently the plasma sheath is thinner which enables closer packing of items to be coated and a deeper penetration of the plasma into holes or edges then in the case of RF activated CVD, which allows for a higher throughput of coated articles.

Lastly, the temperature of the substrate in a pulsed DC PACVD remains below about 130° C. In the case of plasma RF deposition, temperatures rise to above 200° C. which can give rise to more severe thermal expansion effects.

1. A method of coating a surface of an article with a chemical vapour deposition coating comprising:
providing an active electrode;
shielding said active electrode with a dielectric shield having at least one aperture to permit access to the active electrode;
closing said aperture with a dielectricly shielded support post comprising an electively conductive core in electrical communication via said aperture with said active electrode;
placing an article to be coated on said dielectricly shielded support post in electrical communication with said electively conductive core; and
applying a plasma to said article in presence of an electrical current to the article to provide a coating.

2. A method according to claim 1 wherein the chemical vapour deposition coating is a diamond like carbon.

3. A method according to claim 1 wherein the chemical vapour deposition coating is applied by pulse DC PACVD.

4. A method according to claim 1 wherein the chemical vapour deposition coating is applied by RF PACVD.

5. A method according to claim 1 wherein the article is a substantially hollow elongated cylinder of uniform cross section along its length, open at one end with the other end closed or partially closed.

6. A method according to claim 5 wherein the cylinder is of circular cross section.

7. A method according to claim 1 wherein the article is a piston.

8. A method according to claim 1 wherein the electrically conductive core of the shielded support post is maintained in electrical communication with the active electrode by a connector

9. A method according to claim 8 wherein the connector is a threaded connector.

10. A method according to claim 9 wherein the connector is on either the core or the active electrode.

11. A method according to claim 9 wherein the connector is between the core and the active electrode.

12. A method according to claim 1 wherein the article is placed on the shielded support post such that the article covers the top of the shielded support post.

13. A method according to claim 12 wherein the article is placed on the shielded support post such that the article covers the top of the shielded support post and substantially cover the sides of the shielded support post.

14. A method according to claim 1 wherein a cap is applied to the top of the article to be coated.

15. A method according to claim 14 wherein the cap is of corresponding cross section to the article to be coated.

16. A method according to claim 14 wherein the cap is electrically insulated.

17. A method according to claim 14 wherein the cap is in electrical communication with the central core of the support post.

18. A method according to claim 14 wherein the cap is in electrical communication with the article to be coated.

19. A method according to any one of claims 14 wherein the cap is configured for engagement with the conducting core of the support post.

20. A method according to claim 19 wherein the cap is configured for engagement with the conducting core of the support post by means of a thread which engages the post and cap and passes through the article.

21. A method according to claim 19 wherein the cap is configured for engagement with the conducting core of the support post by means of a post which engages and detains the cap to the post, with the article sandwiched there between.

22. A method of coating a surface of a plurality of similar articles with a chemical vapour deposition coating comprising:
providing an active electrode;
shielding said active electrode with a dielectric shield having at least one aperture to permit access to the active electrode;
closing said aperture with a dielectricly shielded support post comprising an electively conductive core in electrical communication via said aperture with said active electrode;
positioning a first article to be coated on said dielectricly shielded support post in electrical communication with said electively conductive core;
positioning a second or subsequent article adjacent to said first article and in electrical communication with said active electrode to provide a contiguous surface and applying a plasma to said articles in presence of an electrical current to the article to provide a coating.

23. A method according to claim 22 wherein the electrical communication between the active electrode is via an intermediate article.

24. A method according to claim 22 wherein the electrical communication is via one or more connectors within said plurality of articles.

25. A method according to claim 24 wherein a cap is positioned above the respective second or subsequent articles.

26. A DLC coated article prepared by a method according to claim 1.

27. A DLC coated article prepared by a method according to claim 22.
